(19) United States
(12) Patent Application Publication
(10) Pub. No.: US 2011/0073748 A1
(43) Pub. Date: Mar. 31, 2011

(54) LIGHT SENSING DEVICE FOR SOLAR TRACKING SYSTEM

(76) Inventor: Ginn-Horng CHAN, Taipei City (TW)

(21) Appl. No.: 12/731,408

(22) Filed: Mar. 25, 2010

(30) Foreign Application Priority Data
Sep. 29, 2009 (TW) 98217946

(51) Int. Cl. H01L 31/0232; H01L 31/09; H01L 31/06

(52) U.S. Cl. 250/203.4

(57) ABSTRACT

A light sensing device for solar tracking system includes a light blocking plate, a light blocking cover, a light guiding element and a light sensor, wherein the light blocking cover comprises an elongate opening facing upward. The light guiding element comprises an elongate light receiving face and a light outputting face and the elongate light receiving face of the light guiding element is exposed to the elongate opening of the light blocking cover for receiving a light from outside. The light sensor is disposed next to the light guiding element to receive the light outputted from the light outputting face and generate an electric signal. The elongate light receiving face renders the light sensor sensitive to the incident angle of the light so as to improve the accuracy of solar tracking system.

### BACKGROUND OF THE INVENTION

1. Field of the Invention

The present invention relates to a light sensing device, more particularly to a light sensing device for solar tracking system.

2. Description of the Related Art

A stationary solar panel may only receive sunlight with a predetermined angle. The incident angle of sunlight with respect to the solar panel varies with latitude, season and time resulting from the revolution and rotation of the earth, so the stationary solar panel may be lack of efficiency in receiving sun's energy. A light tracking controller has been developed to resolve this issue. The light tracking controller utilizes light sensors located at different positions on a solar panel. The light sensors generate electric potential when the light sensors are illuminated. The solar panel may be controlled by a control chip to rotate automatically according to potential differences between the light sensors.

However, a conventional light tracking controller is insensitive to the variation of the position of the sun because the light sensors directly receive sunlight within a wide incident angle, so the tacking accuracy is affected. Besides, the cost of utilizing a CMOS as a light sensor is high, which is a disadvantage to commercial applications. Accordingly, developing a light sensor sensitive to light angle with low cost is a current goal to be achieved.

### SUMMARY OF THE INVENTION

The present invention is directed to provide a light sensing device for solar tracking system utilizing a light guiding element with an elongate light receiving face thereby being sensitive to the incident angle of sunlight to improve the accuracy of a solar tracking system.

One embodiment of light sensing device for solar tracking system according to the present invention comprises a light blocking plate, a light blocking cover, a light guiding element and a light sensor. The light blocking plate is disposed upright. The light blocking cover with a containing space is disposed at one side of the light blocking plate, wherein the light blocking cover includes an elongate opening facing upward. The light guiding element is disposed within the containing space of the light blocking cover, wherein the light guiding element comprises an elongate light receiving face and a light outputting face and the elongate light receiving face of the light guiding element is exposed to the elongate opening of the light blocking cover for receiving a light from outside to pass from the elongate light receiving face of the light guiding element through the light outputting face of the light guiding element. The light sensor is disposed beside the light guiding element for receiving the light emitted from the light outputting face of the light guiding element and generating an electric signal.

One embodiment of the light sensing device for solar tracking system comprises a light blocking plate, two light blocking covers, two light guiding elements and two light sensors. The light blocking plate is disposed upright. Each of two light blocking covers with a containing space, respectively, is disposed at one side of the light blocking plate, wherein each light blocking cover includes an elongate opening facing upward. Each light guiding element is disposed within each containing space of the light blocking cover, wherein each light guiding element comprises an elongate light receiving face and a light outputting face; each elongate light receiving face of the light guiding element is exposed to each elongate opening of the light blocking cover for receiving a light from outside to pass from the elongate light receiving faces of the light guiding elements through the light outputting faces of the light guiding elements. Each light sensor is disposed beside each light guiding element for receiving the light emitted from the light outputting faces of the light guiding elements and generating two electric signals.

### BRIEF DESCRIPTION OF THE DRAWINGS

The objectives, technical contents and characteristics of the present invention can be more fully understood by reading the following detailed description of the preferred embodiments, with reference made to the accompanying drawings, wherein:

FIG. 1 is an exploded view illustrating one embodiment of the light sensing device for solar tracking system according to the present invention;

FIG. 2 is a schematic diagram illustrating one embodiment of the light sensing device for solar tracking system according to the present invention;

FIG. 3 is an exploded view illustrating another embodiment of the light sensing device for solar tracking system according to the present invention;

FIG. 4 is an exploded view illustrating another embodiment of the light sensing device for solar tracking system according to the present invention;

FIG. 5 is a schematic diagram illustrating another embodiment of the light sensing device for solar tracking system according to the present invention;

FIG. 6 illustrates an example of sensing the position of the sun;

FIG. 7 is an exploded view illustrating another embodiment of the light sensing device for solar tracking system according to the present invention;

FIG. 8 is a schematic diagram illustrating another embodiment of the light sensing device for solar tracking system according to the present invention;

FIG. 9 is an exploded view illustrating another embodiment of the light sensing device for solar tracking system according to the present invention;

FIG. 10 is an exploded view illustrating another embodiment of the light sensing device for solar tracking system according to the present invention;

FIG. 11 is a schematic diagram illustrating another embodiment of the light sensing device for solar tracking system according to the present invention

FIG. 12 illustrates another example of sensing the position of the sun.

### DETAILED DESCRIPTION OF THE INVENTION

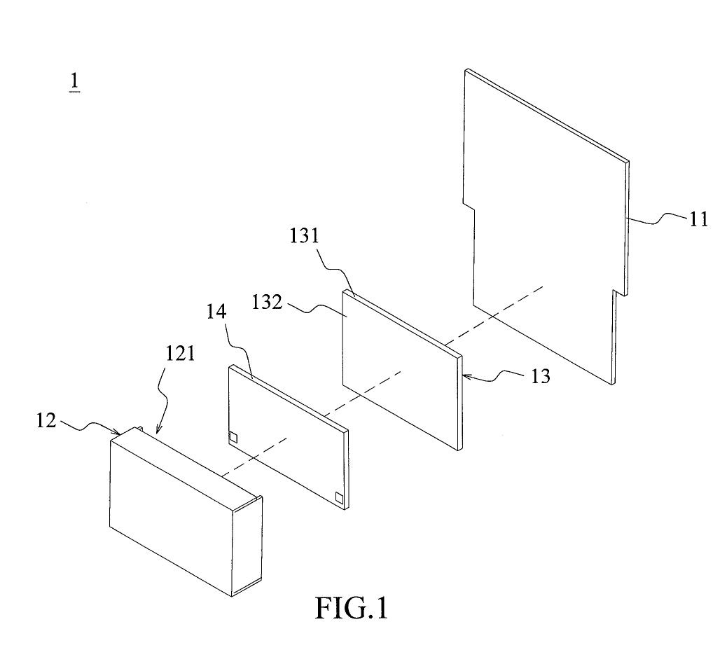

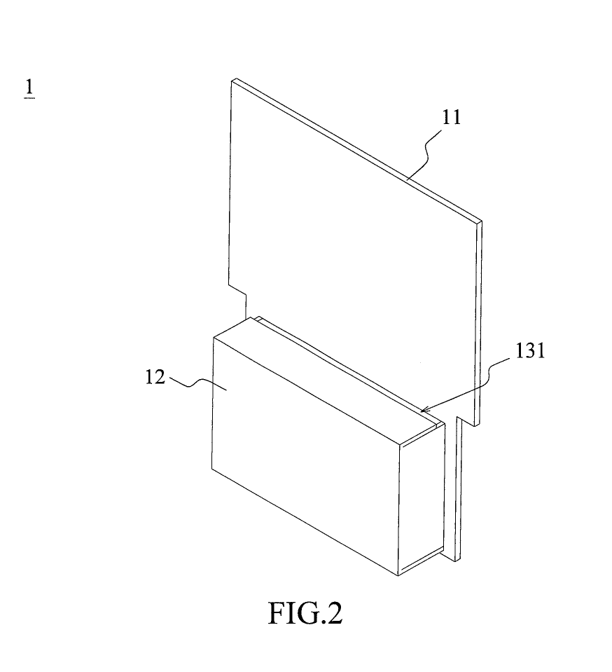

Referring to FIG. 1, FIG. 2, which are respectively a exploded view and a schematic diagram illustrating one embodiment of the light sensing device for solar tracking system 1 according to the present invention. The light sensing device for solar tracking system 1 comprises a light blocking plate 11, a light blocking cover 12, a light guiding element 13 and a light sensor 14. The light blocking plate 11 is disposed upright. The light blocking cover 12 with a containing space is disposed at one side of the light blocking plate 11, wherein the light blocking cover 12 is made integrally or made by a plurality of elements and the light blocking cover 12 includes an elongate opening 121 facing upward. The position of the elongate opening 121 can be, but not limited to, within the range of the light blocking plate 11 so that light comes from the side opposite to where the light blocking cover 12 is located is blocked by the light blocking plate 11 to reach the elongate opening 121. The elongate opening 121 can be, but not limited to, defined by the light blocking plate 11 and the light blocking cover 12 or configured on the light blocking cover 12.

The light guiding element 13 is disposed within the containing space of the light blocking cover 12, wherein the light guiding element 13 comprises an elongate light receiving face 131 and a light outputting face 132 and the elongate light receiving face 131 of the light guiding element 13 is exposed to the elongate opening 121 of the light blocking cover 12 (denoted in FIG. 1), as shown in FIG. 2, for receiving a light from outside to pass from the elongate light receiving face 131 of the light guiding element 13 (denoted in FIG. 1) through the light outputting face 132 (denoted in FIG. 1) of the light guiding element 13 (denoted in FIG. 1). Referring to FIG. 1 again, for example, the light guiding element 13 comprises a light guiding plate. The elongate light receiving face 131 is a side wall of the light guiding element (the light guiding plate) 13. A plurality of reflectors (not shown) are disposed at the face opposite to the light outputting face 132. Reflectors may be ink dots formed by means of screen printing or convex dots formed by means of photolithography. When a light enters into the light guiding element (the light guiding plate) 13 from the elongate light receiving face 131, reflectors reflect the light to the light outputting face 132.

To be continued, the light sensor 14 is disposed beside the light guiding element (the light guiding plate) 13 for receiving the light emitted from the light outputting face 132 of the light guiding element (the light guiding plate) 13 and generating an electric signal, for example, the light sensor 14 may comprise a solar panel or a structure configured by at least one photoresistance or photodiode.

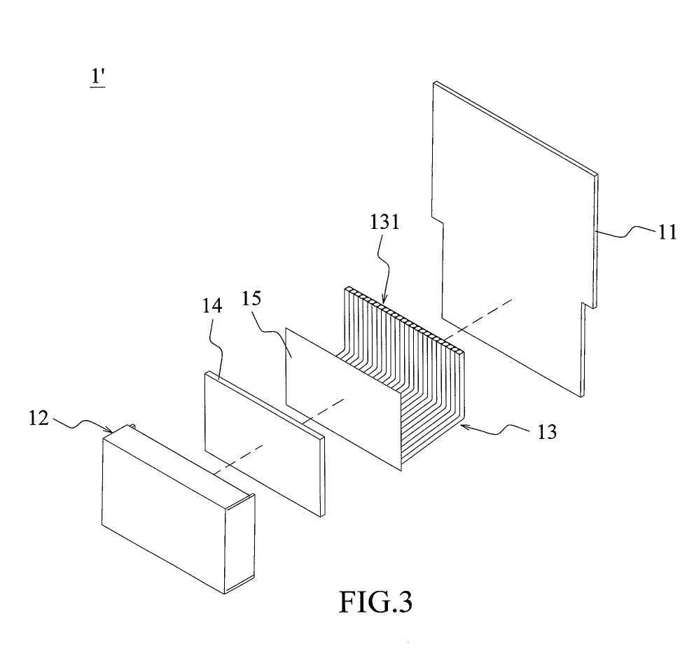

FIG. 3 is an exploded view illustrating another embodiment of the light sensing device for solar tracking system 1′ according to the present invention. The light guiding element 13 of the light sensing device for solar tracking system 1′ may comprise a plurality of optic fibers and the elongate light receiving face 131 is defined by one terminal of each optic fiber while another terminal of each optic fiber facing the light sensor 14. The light sensing device for solar tracking system 1′ further comprises a diffusion plate 15 disposed between the light guiding element 13 (the optic fibers) and the light sensor 14 for evenly diffusing the light emitted from the light guiding element (the optic fibers) 13 to the surface of the light sensor 14.

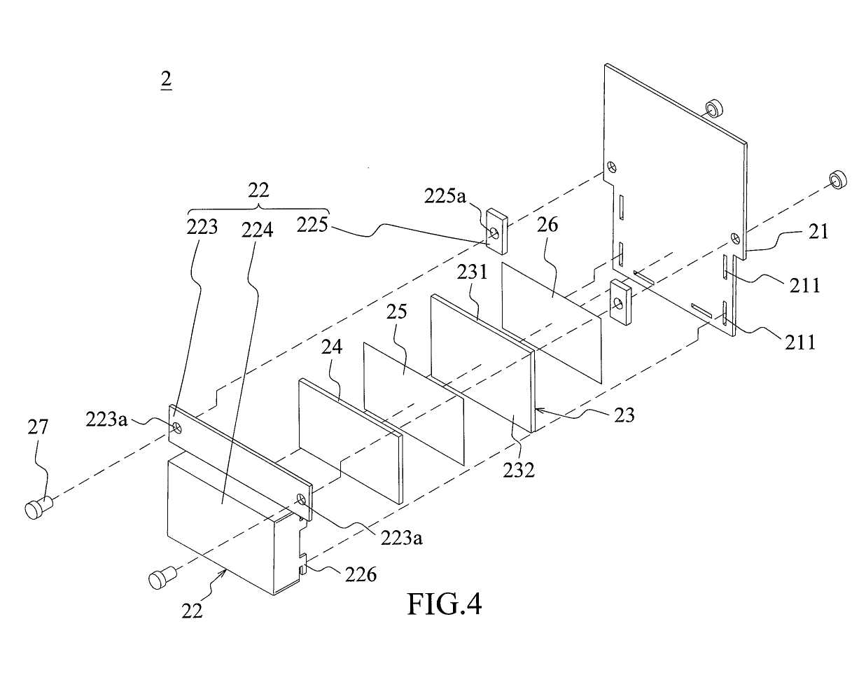

FIG. 4 is an exploded view illustrating another embodiment of the light sensing device for solar tracking system 2 according to the present invention comprising a light blocking plate 21, a light blocking cover 22, a light guiding element 23, a light sensor 24, a reflective plate 26 and a diffusion plate 25. The light blocking plate 21 is disposed upright. Method for disposing the light blocking cover 12 with a containing space at one side of the light blocking plate 11 can be, but not limited to, embedding at least one insert 226 on the light blocking cover 22 into at least one slot 211 on the light blocking plate 21.

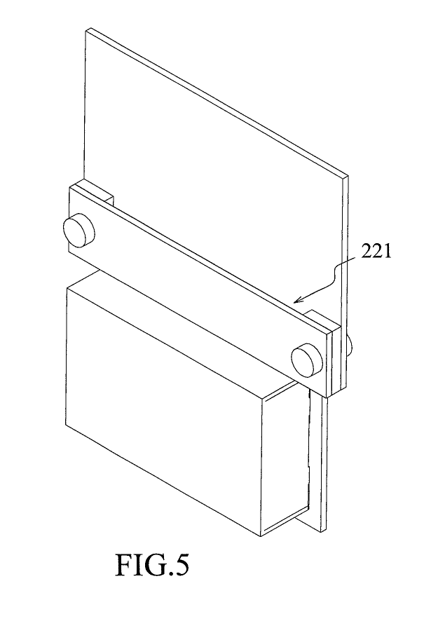

To be continued, the light guiding element 23 is disposed within the containing space of the light blocking cover 22, wherein the light guiding element 23 comprises an elongate light receiving face 231 and a light outputting face 232, for example, the light guiding element 23 comprises a light guiding plate. The elongate light receiving face 231 is a side wall of the light guiding element (the light guiding plate) 23. A plurality of reflectors (not shown) are disposed at the face opposite to the light outputting face 232. Reflectors may be ink dots formed by means of screen printing or convex dots formed by means of photolithography. When a light enters into the light guiding element (the light guiding plate) 23 from the elongate light receiving face 231, reflectors reflect the light to the light outputting face 232. The elongate light receiving face 231 of the light guiding element (the light guiding plate) 23 (denoted in FIG. 4) is exposed to the elongate opening 221 of the light blocking cover 22 (denoted in FIG. 4), as shown in FIG. 5.

Referring to FIG. 4 again, the reflective plate 26 is disposed between the light blocking plate 21 and the light guiding element (the light guiding plate) 23 for improving reflective efficiency. The light sensor 24 is disposed beside the light guiding element (the light guiding plate) 23 for receiving the light emitted from the light outputting face 232 of the light guiding element (the light guiding plate) 23 and generating an electric signal, for example, the light sensor 24 may comprise a solar panel or a structure configured by at least one photoresistance or photodiode. The diffusion plate 25 is disposed between the light guiding element (the light guiding plate) 23 and the light sensor 24 for evenly diffusing the light emitted from the light guiding element (the light guiding plate) 23 to the surface of the light sensor 24.

It should be noted that the light blocking cover 22 is made integrally or made by a plurality of elements, for example, the light blocking cover 22 comprises a light blocking board 223, a light blocking cage 224 and at least one pad 225. Two pads 225, 225 of the light sensing device for solar tracking system 2 are disposed on the light blocking plate 21 and each pad 225 comprises a pad positioning aperture 225a. Two ends of the light blocking board 223 comprise two positioning aperture 223a, 223a, wherein each positioning aperture 223a corresponds to each pad positioning aperture 225a. A locking element 27, such as a screw or a bolt, is configured for penetrating through each positioning aperture 223a and each pad positioning aperture 225a to fix each pad 225 on the end of the light blocking board 223, forming an elongate opening 221 facing upward, as shown in FIG. 5. Besides, two pads 225, 225 may block a lateral direction of light and the position of the elongate opening 221 can be, but not limited to, within the range of the light blocking plate 21.

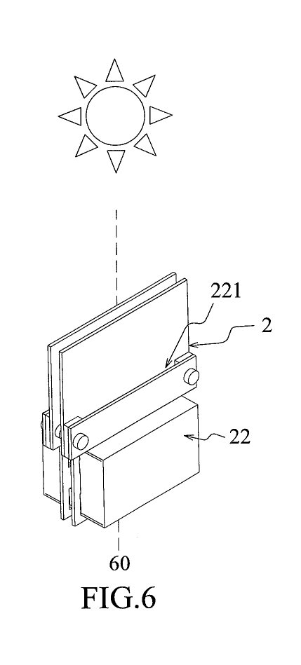

As shown in FIG. 6, two embodiments of the light sensing device for solar tracking system 2, 2 according to the present invention are arranged in symmetrical configuration with respect to a symmetry axis 60 to track the position of the sun. The actuating principle is described as follows: assuming that the sun is on the symmetry axis 60 in the beginning, then two electric signals, such as currents, generated by two light sensors (not shown in FIG. 6) of the light sensing device for solar tracking system 2, 2, respectively, are substantially identical. When the sun deviates from the symmetry axis 60, the two electric signals become different because illuminated areas among two light sensing devices for solar tracking system 2, 2 are different. According to the difference of the two electric signals, a controlling circuit (not shown) electrically connected with two light sensors controls two light sensing device for solar tracking system 2, 2 to rotate with respect to the symmetry axis 60 until the two electric signals become identical. In other words, the sun is on the symmetry axis 60 again and the sun tracking is accomplished. Because the elongate opening 221 of each light blocking cover 22 only allows light within small incident angle range to enter each light guiding element (not shown in FIG. 6) and generate a electric signal, sun tracking becomes sensitive to the variation of the position of the sun. Besides, the light sensing device for solar tracking system 2 according to the present invention may comprise a solar panel or a structure configured by at least one photoresistance or photodiode, so the manufacturing cost is lower than that of a solar tracking system utilizing a CMOS image sensor. The actuation mechanism and principle of the light sensing device for solar tracking system 1 and 1′ are the same as described above. The detail descriptions are skipped herein.

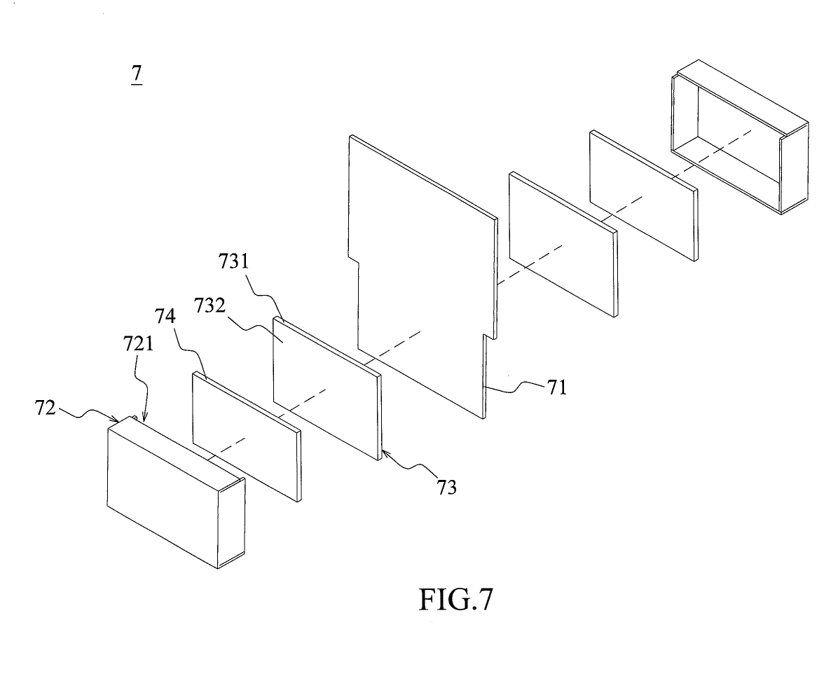

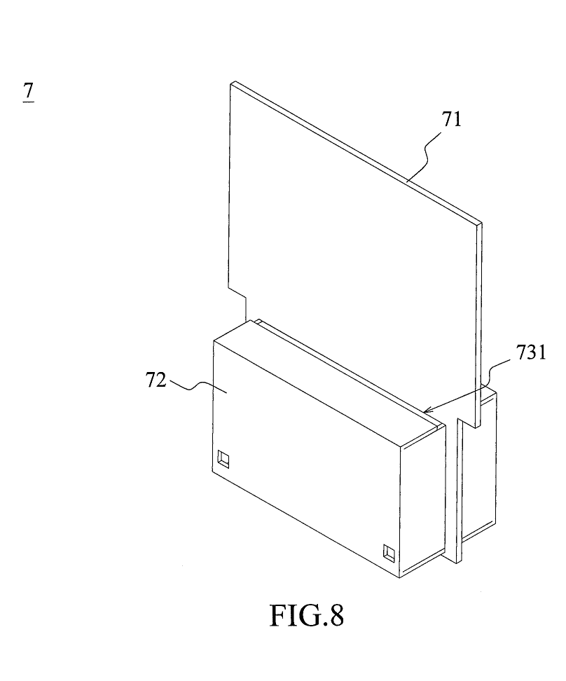

FIG. 7 and FIG. 8 are respectively an exploded view and schematic diagram illustrating another embodiment of the light sensing device for solar tracking system 7 according to the present invention. As shown in FIG. 7, the light sensing device for solar tracking system 7 comprises a light blocking plate 71, two light blocking covers 72, 72, two light guiding elements 73, 73 and two light sensors 74, 74. The light blocking plate 71 is disposed upright. Each of two light blocking covers 72, 72 with a containing space, respectively, is disposed on one side of the light blocking plate 71, wherein each light blocking cover 72 includes an elongate opening 721 facing upward. The position of each elongate opening 721 can be, but not limited to, within the range of the light blocking plate 71 so that light comes from the side opposite to where each light blocking cover 72 is located is blocked by the light blocking plate 71 to reach each elongate opening 721. Each elongate opening 721 can be, but not limited to, defined by the light blocking plate 71 and each light blocking cover 72 or configured on each light blocking cover 72.

Each light guiding elements 73 is disposed within each containing space of the light blocking cover 72, wherein each light guiding element 73 comprises an elongate light receiving face 731 and a light outputting face 732; each elongate light receiving face 731 of the light guiding element 73 is exposed to each elongate opening 721 of the light blocking cover 72 (denoted in FIG. 7), as shown in FIG. 8, for receiving a light from outside to pass from each elongate light receiving faces 731 of the light guiding element 73 (denoted in FIG. 7) through each light outputting face 732 of the light guiding element 73 (denoted in FIG. 7). Referring to FIG. 7 again, for example, each light guiding element 73 comprises a light guiding plate. Each elongate light receiving face 731 is a side wall of each light guiding element (the light guiding plate) 73. A plurality of reflectors (not shown) are disposed at the face opposite to each light outputting face 732. Reflectors may be ink dots formed by means of screen printing or convex dots formed by means of photolithography. When a light enters into each light guiding element (the light guiding plate) 73 from each elongate light receiving face 731, reflectors reflect the light to each light outputting face 732.

To be continued, each light sensor 74 is disposed beside each light guiding element (the light guiding plate) 73 for receiving the light emitted from each light outputting face 732 of each light guiding element (the light guiding plate) 73 and each light sensor 74 generates a electric signal, for example, each light sensor 74 may comprise a solar panel or a structure configured by at least one photoresistance or photodiode.

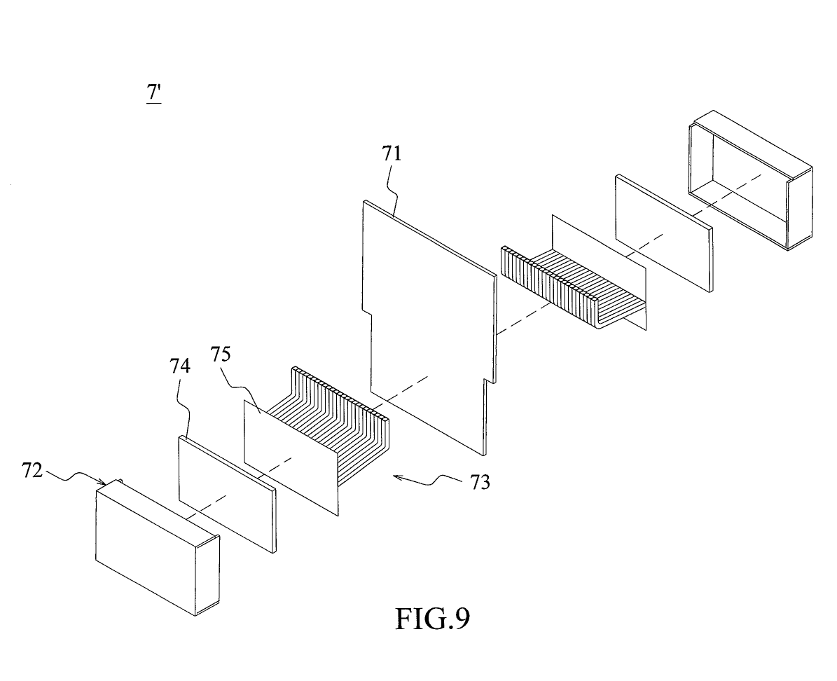

FIG. 9 is an exploded view illustrating another embodiment of the light sensing device for solar tracking system 7′ according to the present invention. Each light guiding element 73 of the light sensing device for solar tracking system 7′ may comprise a plurality of optic fibers and each elongate light receiving face 731 is defined by one terminal of each optic fiber while another terminal of each optic fiber facing the light sensor 74. The light sensing device for solar tracking system 7′ further comprises a diffusion plate 75 disposed between each light guiding element (the optic fibers) 73 and each light sensor 74 for evenly diffusing the light emitted from each light guiding element (the optic fibers) 73 to the surface of each light sensor 74.

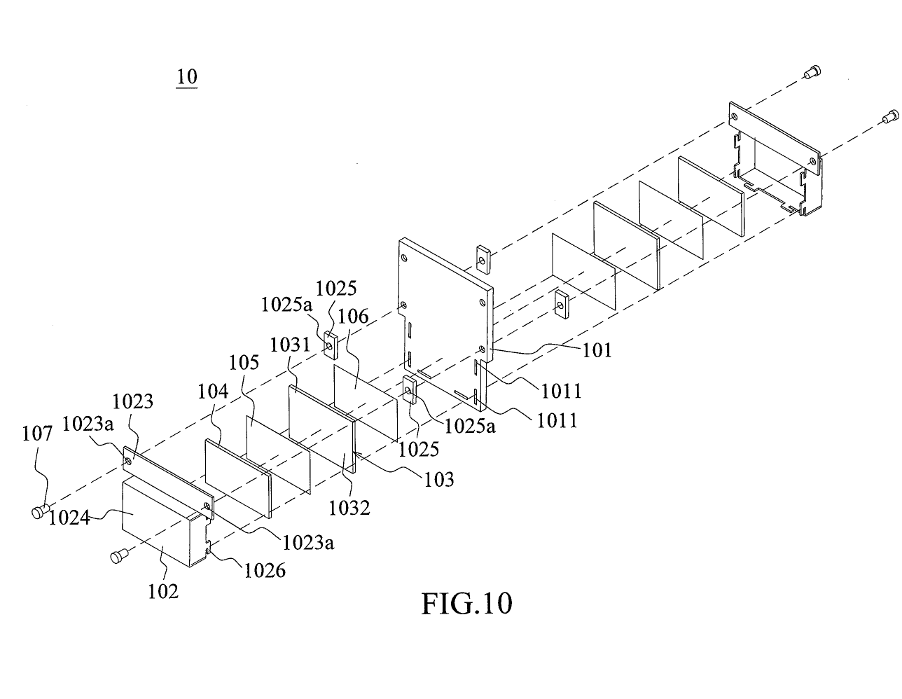

FIG. 10 is an exploded view illustrating another embodiment of the light sensing device for solar tracking system 10 according to the present invention comprising a light blocking plate 101, two light blocking covers 102, 102, two light guiding elements 103, 103, two light sensors 104, 104, two reflective plates 106, 106 and two diffusion plates 105, 105. The light blocking plate 101 is disposed upright. Method for disposing each light blocking cover 102 with a containing space at one side of the light blocking plate 101 can be, but not limited to, embedding at least one insert 1026 on each light blocking cover 102 into at least one slot 1011 on the light blocking plate 101.

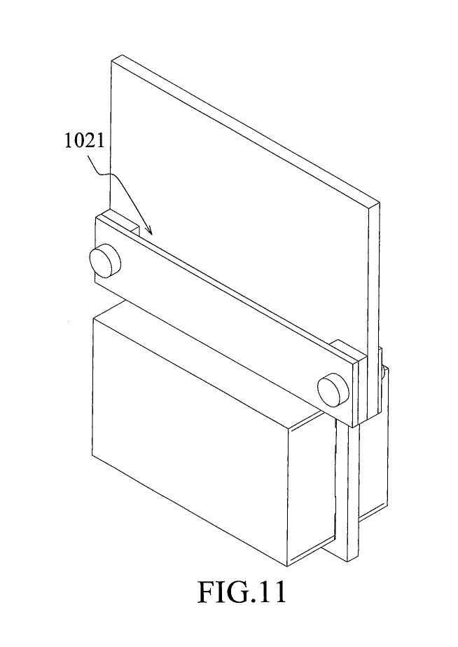

To be continued, each light guiding element 103 is disposed within the containing space of each light blocking cover 102, wherein each light guiding element 103 comprises an elongate light receiving face 1031 and a light outputting face 1032, for example, the light guiding element 103 comprises a light guiding plate. The elongate light receiving face 1031 is a side wall of each light guiding element (the light guiding plate) 103. A plurality of reflectors (not shown) are disposed at the face opposite to the light outputting face 1032. Reflectors may be ink dots formed by means of screen printing or convex dots formed by means of photolithography. When a light enters into each light guiding element (the light guiding plate) 103 from the elongate light receiving face 1031, reflectors reflect the light to the light outputting face 1032. The elongate light receiving face 1031 of each light guiding element (the light guiding plate) 103 (denoted in FIG. 10) is exposed to the elongate opening 1021 of each light blocking cover 102 (denoted in FIG. 10), as shown in FIG. 11.

Referring to FIG. 10 again, each reflective plate 106 is disposed between the light blocking plate 101 and each light guiding element (the light guiding plate) 103 for improving reflective efficiency. Each light sensor 104 is disposed beside each light guiding element (the light guiding plate) 103 for receiving the light emitted from the light outputting face 1032 of each light guiding element (the light guiding plate) 103 and generating an electric signal, for example, each light sensor 104 may comprise a solar panel or a structure configured by at least one photoresistance or photodiode. Each diffusion plate 105 is disposed between each light guiding element (the light guiding plate) 103 and each light sensor 104 for evenly diffusing the light emitted from each light guiding element (the light guiding plate) 103 to the surface of each light sensor 104.

It should be noted that each light blocking cover 102 is made integrally or made by a plurality of elements, for example, each light blocking cover 102 comprises a light blocking board 1023, a light blocking cage 1024 and at least one pad 1025. Two pads 1025, 1025 of the light sensing device for solar tracking system 10 are disposed on the light blocking plate 101 and each pad 1025 comprises a pad positioning aperture 1025a. Two ends of the light blocking board 1023 comprise two positioning aperture 1023a, 1023a, wherein each positioning aperture 1023a corresponds to each pad positioning aperture 1025a. A locking element 107, such as a screw or a bolt, is configured for penetrating through each positioning aperture 1023a and each pad positioning aperture 1025a to fix each pad 1025 on the end of the light blocking board 1023, forming an elongate opening 1021 facing upward, as shown in FIG. 11. Besides, two pads 1025, 1025 may block a lateral direction of light and the position of each elongate opening 1021 can be, but not limited to, within the range of the light blocking plate 101.

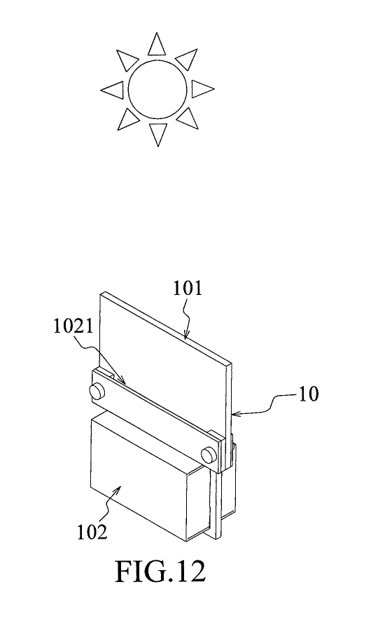

As shown in FIG. 12, the actuating principle of the embodiment of the light sensing device for solar tracking system 10 according to the present invention is described as follows: assuming that the sun is on the extension line of the light blocking plate 101 in the beginning, and then two electric signals, such as currents, generated by two light sensors (not shown in FIG. 12) of the light sensing device for solar tracking system 10 are substantially identical. When the sun deviates from the extension line of the light blocking plate 101, the two electric signals become different because illuminated areas among two light guiding elements (not shown in FIG. 12) of light sensing device for solar tracking system 10 are different. According to the difference of the two electric signals, a controlling circuit (not shown) electrically connected with two light sensors controls a motor (not shown) attached to the light sensing device for solar tracking system 10 to rotate until the two electric signals become identical. In other words, the sun is on the extension line of the light blocking plate 101 again and the sun tracking is accomplished. Because the elongate opening 1021 of each light blocking cover 102 only allows light within small incident angle range to enter each light guiding element (not shown in FIG. 12) and generate a electric signal, sun tracking becomes sensitive to the variation of the position of the sun. Besides, the light sensing device for solar tracking system 10 according to the present invention may comprise a solar panel or a structure configured by at least one photoresistance or photodiode, so the manufacturing cost is lower than that of a solar tracking system utilizing a CMOS image sensor. The actuation mechanism and principle of the light sensing device for solar tracking system 7 and 7′ are the same as described above. The detail descriptions are skipped herein.

To sum up, the difference of electric signals between light sensors of the light sensing device for solar tracking system according to the present invention is utilized to track the sun, besides the elongate light receiving face of the light guiding element make the light sensing device sensitive to the variation of the position of the sun, so as to improve the accuracy of the sun tracking system.

The embodiments described above are to demonstrate the technical contents and characteristics of the preset invention to enable the persons skilled in the art to understand, make, and use the present invention. However, it is not intended to limit the scope of the present invention. Therefore, any equivalent modification or variation according to the spirit of the present invention is to be also included within the scope of the present invention.

What is claimed is:

1. A light sensing device for solar tracking system comprising:
a light blocking plate disposed upright;
a light blocking cover with a containing space disposed at one side of said light blocking plate, wherein said light blocking cover includes an elongate opening facing upward;
a light guiding element disposed within said containing space, wherein said light guiding element comprises an elongate light receiving face and a light outputting face and said elongate light receiving face of said light guiding element is exposed to said elongate opening of said light blocking cover for receiving a light from outside to pass from said elongate light receiving face of said light guiding element through said light outputting face of said light guiding element; and
a light sensor disposed beside said light guiding element for receiving said light emitted from said light outputting face of said light guiding element and generating an electric signal.

2. The light sensing device for solar tracking system according to claim 1, wherein said light guiding element includes a light guiding plate and then said elongate light receiving face is a side wall of said light guiding plate.

3. The light sensing device for solar tracking system according to claim 2, further comprising a reflective plate disposed between said light blocking plate and said light guiding element for reflecting said light to said light outputting face of said light guiding plate.

4. The light sensing device for solar tracking system according to claim 2, further comprising a diffusion plate disposed between said light guiding plate and said light sensor for evenly diffusing said light emitting from said light guiding plate to the surface of said light sensor.

5. The light sensing device for solar tracking system according to claim 1, wherein said light blocking cover further comprises at least one pad disposed on said light blocking plate.

6. The light sensing device for solar tracking system according to claim 1, wherein said light guiding element comprises a plurality of optic fibers and said elongate light receiving face is defined by one terminal of each said optic fibers while another terminal of each said optic fibers facing said light sensor.

7. The light sensing device for solar tracking system according to claim 6, further comprising a diffusion plate disposed between said optic fibers and said light sensor for evenly diffusing said light emitting from said optic fibers to the surface of said light sensor.

8. The light sensing device for solar tracking system according to claim 1, wherein said light sensor comprises a solar panel, at least one photoresistance or at least one photodiode.

9. The light sensing device for solar tracking system according to claim 1, wherein said light blocking cover is made integrally or made by a plurality of elements.

10. The light sensing device for solar tracking system according to claim 1, wherein said elongate opening is defined by said light blocking plate and said light blocking cover or configured on said light blocking cover.

11. A light sensing device for solar tracking system comprising:
a light blocking plate disposed upright;
two light blocking covers, wherein each of said two light blocking covers with a containing space, respectively, is disposed on one side of said light blocking plate, wherein each said light blocking cover includes an elongate opening facing upward;
two light guiding elements, wherein each said light guiding element is disposed within each said containing space, wherein each said light guiding element comprises an elongate light receiving face and a light outputting face; each said elongate light receiving face of said light guiding element is exposed to each said elongate opening of said light blocking cover for receiving a light from outside to pass from each said elongate light receiving face of said light guiding element through each said light outputting face of said light guiding element; and
two light sensors, wherein each said light sensor is disposed beside each said light guiding element for receiving said light emitted from each said light outputting face of each said light guiding element and each said light sensor generates a electric signal.

12. The light sensing device for solar tracking system according to claim 11, wherein said light guiding elements include light guiding plates and each said elongate light receiving face is a side wall of each said light guiding plate.

13. The light sensing device for solar tracking system according to claim 12, further comprising two reflective plates disposed between said light blocking plate and each said light guiding element, respectively, for reflecting said light to said light outputting faces of said light guiding plates.

14. The light sensing device for solar tracking system according to claim 12, further comprising two diffusion plates disposed between each said light guiding plate and each said light sensor, respectively, for evenly diffusing said light emitting from each said light guiding plate to the surface of each said light sensor.

15. The light sensing device for solar tracking system according to, claim 11, wherein each said light blocking cover further comprises at least one pad disposed on said light blocking plate.

16. The light sensing device for solar tracking system according to claim 11, wherein each said light guiding element is configured by a plurality of optic fibers and each said elongate light receiving face is defined by one terminal of each said optic fiber while another terminal of each said optic fibers facing each said light sensor.

17. The light sensing device for solar tracking system according to claim 16, further comprising two diffusion plates respectively disposed between said optic fibers and each said light sensor for evenly diffusing said light emitting from said optic fibers to the surface of each said light sensor.

18. The light sensing device for solar tracking system according to claim 11, wherein each said light sensors comprises a solar panel, at least one photoresistance or at least one photodiode.

19. The light sensing device for solar tracking system according to claim 11, wherein each said light blocking cover is made integrally or made by a plurality of elements.

20. The light sensing device for solar tracking system according to claim 11, wherein each said elongate opening is defined by said light blocking plate and each said light blocking cover or configured on each said light blocking cover.
